(19) United States
(12) Patent Application Publication
(10) Pub. No.: US 2009/0058552 A1
(43) Pub. Date: Mar. 5, 2009

(54) HIGH-FREQUENCY MODULE, AND MOBILE TELEPHONE AND ELECTRONIC DEVICE PROVIDED THEREWITH

(76) Inventor: Koji OIWA, Osaka-shi (JP)

Correspondence Address: BIRCH STEWART KOLASCH & BIRCH, PO BOX 747, FALLS CHURCH, VA, 22040-0747, US

(21) Appl. No.: 12/122,209

(22) Filed: May 16, 2008

(30) Foreign Application Priority Data
Aug. 30, 2007 (JP) 2007-223785

(51) Int. Cl. H03H 7/38

(52) U.S. Cl. 333/32

(57) ABSTRACT

A high-frequency module includes: a mixer circuit performing frequency conversion by mixing a local oscillation signal with a reception signal; a filter circuit eliminating an unnecessary frequency component from the signal outputted from the mixer circuit; a controllable-gain amplifier circuit amplifying and outputting the signal outputted from the filter circuit; and an impedance circuit (such as a resistive element, inductance element, or a chip bead) interposed between the output terminal of the amplifier circuit and the input terminal of a demodulation circuit in the succeeding stage so as to apparently increase the input impedance of the demodulation circuit.

### CROSS-REFERENCE TO RELATED APPLICATIONS

This nonprovisional application claims priority under 35 U.S.C. §119(a) on Patent Application No. 2007-223785 filed in Japan on Aug. 30, 2007, the entire contents of which are hereby incorporated by reference.

### BACKGROUND OF THE INVENTION

1. Field of the Invention

The present invention relates to a high-frequency module for use in a portable television set, a portable DVD (digital versatile disc) device, a mobile telephone, a PMP (portable multimedia player) or the like, and also relates to a mobile telephone and a mobile electronic device incorporating such a high-frequency module.

2. Description of Related Art

Conventional high-frequency modules (for example, a one-segment tuner module) typically include a mixer circuit that performs frequency conversion by mixing a local oscillation signal with a reception signal, a filter circuit that eliminates unnecessary frequency components from the signal outputted from the mixer circuit and a controllable-gain amplifier circuit that amplifies and outputs the signal outputted from the filter circuit. The output terminal of the amplifier circuit is either directly connected to the input terminal of a demodulation circuit in the succeeding stage with no element interposed therebetween, or is connected thereto only through a DC blocking capacitor.

One example of the conventional technology related to the foregoing is disclosed in JP-A-2007-174399 by the applicant of the present invention.

Incidentally, low power consumption is one of the important capabilities of a high-frequency module used in a portable television set, a portable DVD device, a mobile telephone, a PMP or the like. Since long life is required in the battery of an appliance, power consumption is reduced as much as possible in all components including a high-frequency module.

In the conventional high-frequency module, low power consumption is essential, the controllable-gain amplifier circuit included in the conventional high-frequency module is required to consume as little current as possible within the limit of performance

As described previously, in the conventional high-frequency module, however, the output terminal of the amplifier circuit is either directly connected to the input terminal of the demodulation circuit in the succeeding stage with no element interposed therebetween, or is connected thereto only through the DC blocking capacitor. Thus, unless the input impedance of the demodulation circuit in the succeeding stage is sufficiently high, the distortion performance of the amplifier circuit may deteriorate. This prevents power consumption from being reduced to below a particular level.

Naturally, if a higher current is passed through the amplifier circuit, the poor performance can be avoided; however, this disadvantageously reduces the battery life of an appliance. Thus, there is a trade-off between different aspects of performance.

If the input impedance of the demodulation circuit is sufficiently high, the amplifier circuit is not affected, and thus the distortion performance of the amplifier circuit is not degraded. Disadvantageously, however, the use of the demodulation circuit having sufficiently high input impedance results in high cost.

When the distortion performance of the amplifier circuit deteriorates, an intermediate frequency signal is distorted, and thus noise is increased (C/N (carrier to noise) value is degraded). This prevents a noise-free signal from being transmitted to the demodulation circuit in the succeeding stage, thus leading to degraded reception sensitivity.

### SUMMARY OF THE INVENTION

An object of the present invention is to provide a high-frequency module that achieves improved reception sensitivity without increasing consumption current and cost, and to provide a mobile telephone and a mobile electronic device incorporating such a high-frequency module.

To achieve the above object, a high-frequency module according to the present invention includes: a mixer circuit performing frequency conversion by mixing a local oscillation signal with a reception signal; a filter circuit eliminating an unnecessary frequency component from a signal outputted from the mixer circuit; a controllable-gain amplifier circuit amplifying and outputting a signal outputted from the filter circuit; and an impedance circuit (or a resistive element, an inductance element or a chip bead) interposed between an output terminal of the amplifier circuit and an input terminal of a demodulation circuit in the stage succeeding the amplifier circuit so as to apparently increase an input impedance of the demodulation circuit.

The high-frequency module according to the present invention can use various configurations other than the configuration described above; these configurations will be described in detail.

### BRIEF DESCRIPTION OF THE DRAWINGS

FIG. 1 is a block diagram schematically showing the configuration of a high-frequency module (a one-segment tuner module) according to the present invention;

FIG. 2 is a circuit diagram showing the one-segment tuner module 1 of a first embodiment;

FIG. 3 is a circuit diagram showing the one-segment tuner module 1 of a second embodiment;

FIG. 4 is a circuit diagram showing the one-segment tuner module 1 of a third embodiment;

FIG. 5 is a circuit diagram showing the one-segment tuner module 1 of a fourth embodiment;

FIG. 6 is a circuit diagram showing the one-segment tuner module 1 of a fifth embodiment;

FIG. 7 is a circuit diagram showing the one-segment tuner module 1 of a sixth embodiment;

FIG. 8 is a circuit diagram showing the one-segment tuner module 1 of a seventh embodiment; and

FIG. 9 is a circuit diagram showing the one-segment tuner module 1 of an eighth embodiment.

### DETAILED DESCRIPTION OF PREFERRED EMBODIMENTS

Hereinafter, a detailed description will be given of a case where the present invention is applied to a one-segment tuner module as an example of high-frequency modules for use in a portable television set, a portable DVD device, a mobile telephone, a PMP and the like.

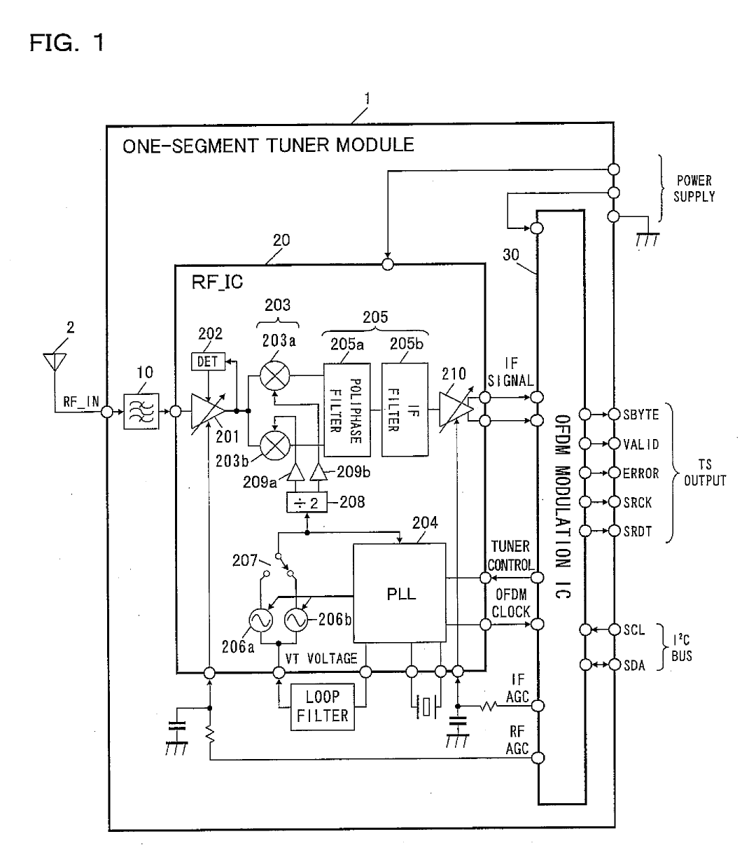

FIG. 1 is a block diagram schematically showing the configuration of a high-frequency module (a one-segment tuner module) according to the invention.

The one-segment tuner module 1 shown in FIG. 1 serves as a circuit that receives a desired program from a station selected from television broadcast stations that transmit one-segment broadcast.

A one-segment broadcast signal received by an antenna 2 is fed from the antenna 2 to the high-frequency signal input terminal (RF_IN) of the one-segment tuner module 1, and is fed, through a UHF filter 10 that passes only signals within the UHF (ultra high frequency) band for one-segment broadcast signals, to a variable gain amplifier circuit 201 (hereinafter, “RF_VGA circuit 201”) for high-frequency signals incorporated in a high-frequency signal processing IC 20 (hereinafter, “RF_IC 20”).

The RF_VGA circuit 201 serves as an amplifier circuit that can control gain so as to prevent distortion of the signal processed by the RF_VGA circuit 201 itself and the circuits in the succeeding stages even when a high-power one-segment broadcast signal is received. Basically, according to a control signal (an RF_AGC voltage) outputted from an OFDM (orthogonal frequency division multiplexing) demodulation IC 30 included in the succeeding stage in the one-segment tuner module 1, the RF_VGA circuit 201 operates at an appropriate gain to prevent degraded reception due to distortion.

Some types of the RF_VGA circuits 201 include a function section (a received power detector circuit 202 shown in FIG. 1) that detects received power by itself; some types of the RF_VGA circuits 201 optimize gain automatically by themselves.

The one-segment broadcast signal converted by the RF_VGA circuit 201 into a signal of an appropriate level is fed to the mixer circuit 203, where the signal is converted into an intermediate frequency signal (hereinafter, “an IF signal”) so as to be easily processed in the OFDM modulation IC 30 in the succeeding stage.

The mixer circuit 203 basically uses a superheterodyne configuration; it receives the one-segment broadcast signal to be received and a local oscillation signal having a frequency lower (or higher) than that of the one-segment broadcast signal by a predetermined intermediate frequency, and outputs the IF signal that is the frequency-difference component between these incoming signals.

The IF signal is held at a constant frequency by a PLL (phase locked loop) circuit 204 (including an external quartz crystal and an external loop filter); it typically is a signal having a frequency of 1 MHz or less so that it can be demodulated by the OFDM modulation IC 30.

In FIG. 1, two mixer circuits 203a and 203b are used as the mixer circuit 203, and as a filter circuit 205 connected to the stage succeeding the mixer circuit 203, a polyphase filter 205a is provided in addition to an IF filter 205b. This configuration is used to eliminate image interference that cannot be avoided with the mixer circuit using the superheterodyne configuration.

When the frequency of the IF signal is set at 1 MHz or less, an image interference frequency falls within the reception band of broadcast signals. Thus, unless this configuration is used, the reception sensitivity is degraded, and at worst, the reception is not achieved.

In FIG. 1, two local oscillation signal generation circuits 206a and 206b are switched by a switch 207 so that the entire UHF band is covered by the low-frequency local oscillation signal generation circuit 206a and the high-frequency local oscillation signal generation circuit 206b.

In FIG. 1, the local oscillation signal is frequency-divided with a frequency divider 208; this is because of the following reason. In order to improve phase noise performance, the local oscillation signal generation circuits 206a and 206b generate a local oscillation signal having two times the frequency that is eventually needed. Thus, before the mixer circuit 203 receives the signal, the frequency of the local oscillation signal generated by the local oscillation signal generation circuits 206a and 206b needs to be divided in half. The signal generated by the frequency divider 208 is fed to the mixer circuits 203a and 203b through buffers 209a and 209b.

The IF signal outputted from the mixer circuit 203 is fed, through the filter circuit 205 (consisting of the polyphase filter 205a and the IF filter 205b in an example shown in FIG. 1), to a variable gain amplifier circuit 210 (hereinafter, “IF_VGA circuit 210”) for IF signals.

The filter circuit 205 serves to eliminate the unnecessary frequency components (noise) other than the IF signal so as not to amplify the unnecessary noise in the IF_VGA circuit 210 and other circuits in the succeeding stages.

The IF_VGA circuit 210 is a controllable-gain amplifier. Basically, according to a control signal (an IF_AGC voltage) outputted from the OFDM demodulation IC 30 included in the succeeding stage in the one-segment tuner module 1, the IF_VGA circuit 210 operates at an appropriate gain and operates so that the best demodulation performance is obtained when the demodulation operation is performed in the OFDM demodulation IC 30.

As shown in FIG. 1, one-segment tuner modules are typically composed of an RF_IC 20, an OFDM demodulation IC 30 and peripheral circuits; here, the RF_IC 20 typically includes the functions of the circuits from the RF_VGA circuit 201 to the IF_VGA circuit 210 described above.

The OFDM demodulation IC 30 serves as a circuit that subjects the IF signal outputted from the RF_IC 20 to OFDM demodulation.

TS output signals (SBYTE, VALID, ERROR, SRCK and SRDT) outputted from the OFDM modulation IC 30 are decoded into a video signal, an audio signal and data in a back-end IC (digital decoding circuit) connected to the succeeding stage in the one-segment tuner module 1; the video signal is fed to a liquid crystal panel module, where video and data information are viewed, and the audio signal is fed to a speaker, where sound is heard.

Today, digital decoding is sometimes performed by software on a personal computer or the like. Thus, video can be viewed and sound can be heard without the need for a back-end IC.

As described above, the one-segment tuner module 1 serves as a high-frequency module that integrates these functions into one package and that can be controlled from the host IC or personal computer of an appliance by communication through an I²C bus or the like.

Now, the unique configuration of the one-segment tuner module 1 will be described in detail.

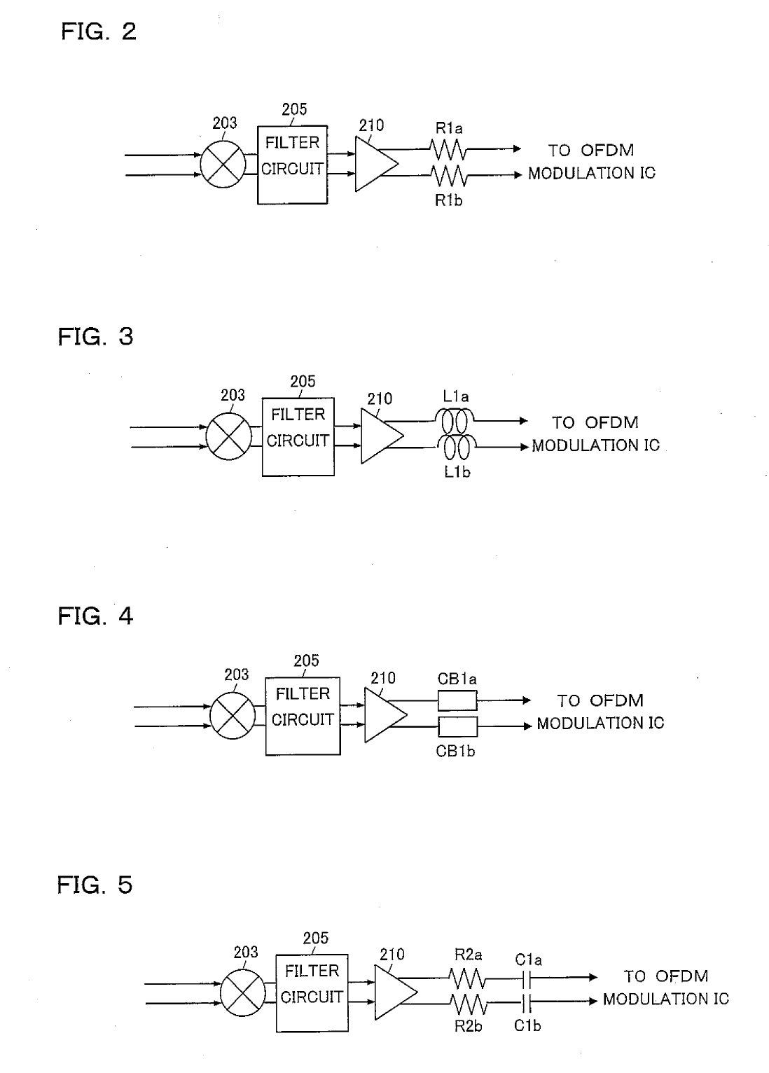

FIG. 2 is a circuit diagram showing the one-segment tuner module 1 of a first embodiment.

As shown in FIG. 2, in the one-segment tuner module 1 of the first embodiment, one or more resistive elements (resistors R1a and R1b in FIG. 2) are interposed in series between the output terminals of the IF_VGA circuit 210 and the input terminals of the OFDM modulation IC 30 in the stage succeeding the IF_VGA circuit 210.

By interposing the resistors R1a and R1b in this way, it is possible to apparently increase the input impedance of the OFDM modulation IC 30 as seen from the IF_VGA circuit 210.

The resistance of the resistors R1a and R1b is preferably about 100Ω, as experimentally found; even when the input impedance of the OFDM modulation IC 30 is as low as about 100Ω, the apparent input impedance of the OFDM modulation IC 30 is increased to about 300Ω by interposing the resistors R1a and R1b.

Hence, without increased consumption current and cost, the influence from the succeeding stage on the IF_VGA circuit 210 can be reduced. Thus, it is possible to improve the distortion performance of the IF_VGA circuit 210. Even if the current through the IF_VGA circuit 210 is decreased, the distortion performance can be maintained.

As the resistance of the resistors R1a and R1b is increased, the distortion performance of the IF_VGA circuit 210 is improved. However, as the resistance of the resistors R1a and R1b is increased, the signal is attenuated. Thus, the resistance is limited to up to about 1 kΩ, as experimentally found.

Even when the output bias potential of the IF_VGA circuit 210 differs from the input bias potential of the OFDM modulation IC 30 for some reason by interposing the resistors R1a and R1b, the difference can be accommodated by the interposed resistors R1a and R1b. Thus, it is possible to prevent degraded performance due to the difference between the biases.

FIG. 3 is a circuit diagram showing the one-segment tuner module 1 of a second embodiment.

As shown in FIG. 3, in the one-segment tuner module 1 of the second embodiment, one or more inductance elements (coils L1a and L1b in FIG. 3) are interposed in series between the output terminals of the IF_VGA circuit 210 and the input terminals of the OFDM modulation IC 30 in the stage succeeding the IF_VGA circuit 210.

By interposing the coils L1a and L1b in this way, it is possible to apparently increase the input impedance of the OFDM modulation IC 30 as seen from the IF_VGA circuit 210.

The second embodiment where the inductance elements are interposed differs from the first embodiment where the resistive elements are interposed in that a LPF (low pass filter) is formed by input capacitance (unillustrated) of the OFDM modulation IC 30 and the interposed inductance elements. Thus, it is possible to reduce the distortion, and the harmonic components in it in particular, occurring in the IF_VGA circuit 210. This makes it possible to obtain benefits similar to those of the first embodiment where the resistive elements are interposed.

FIG. 4 is a circuit diagram showing the one-segment tuner module 1 of a third embodiment.

As shown in FIG. 4, in the one-segment tuner module 1 of the third embodiment, one or more chip beads (chip beads CB1a and CB1b in FIG. 4) are interposed in series between the output terminals of the IF_VGA circuit 210 and the input terminals of the OFDM modulation IC 30 in the stage succeeding the IF_VGA circuit 210.

By interposing the chip beads CB1a and CB1b in this way, as in the first and second embodiments, it is possible to apparently increase the input impedance of the OFDM modulation IC 30 as seen from the IF_VGA circuit 210.

The third embodiment where the chip beads are interposed differs from the second embodiment where the inductance elements are interposed in that a LPF is formed by chip beads alone irrespective of the input capacitance of the OFDM modulation IC 30. Thus, it is possible to stably obtain the benefits of the present invention with little variation in results.

FIG. 5 is a circuit diagram showing the one-segment tuner module 1 of a fourth embodiment.

As shown in FIG. 5, in the one-segment tuner module 1 of the fourth embodiment, one or more resistive elements (resistors R2a and R2b in FIG. 5) and one or more DC blocking capacitor elements (capacitors C1a and C1b in FIG. 5) are interposed in series between the output terminals of the IF_VGA circuit 210 and the input terminals of the OFDM modulation IC 30 in the stage succeeding the IF_VGA circuit 210. Instead of the resistive elements, inductance elements or chip beads may be interposed as shown in the second and third embodiments.

By interposing the resistors R2a and R2b (or inductance elements or chip beads) in this way, as in the first embodiment, it is possible to apparently increase the input impedance of the OFDM modulation IC 30 as seen from the IF_VGA circuit 210.

Since the capacitors C1a and C1b are additionally interposed, degraded performance due to the difference between the biases cannot be prevented As in the first to third embodiments, however, the apparently increased input impedance of the OFDM modulation IC 30 can be expected.

The configuration of the fourth embodiment is preferably used when the output bias potential of the IF_VGA circuit 210 sufficiently differs from the input bias potential of the OFDM modulation IC 30.

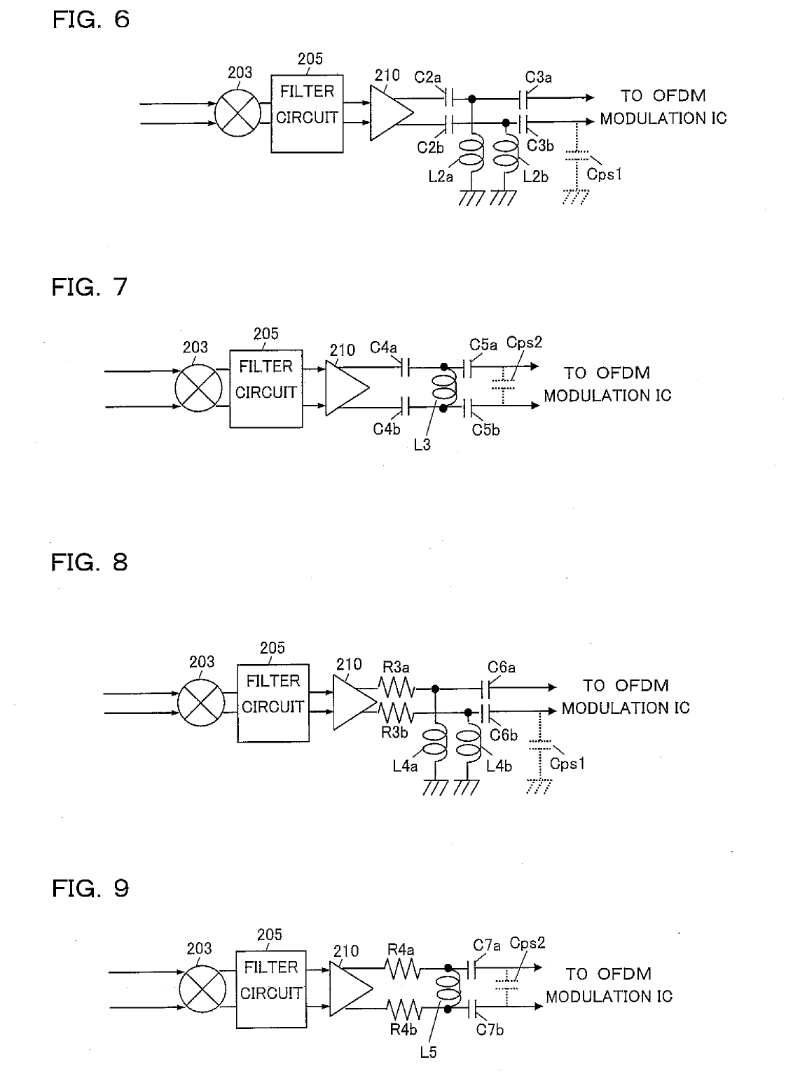

FIG. 6 is a circuit diagram showing the one-segment tuner module 1 of a fifth embodiment.

As shown in FIG. 6, in the one-segment tuner module 1 of the fifth embodiment, one or more DC blocking capacitor elements (capacitors C2a, C2b, C3a and C3b in FIG. 6) are interposed in series between the output terminals of the IF_VGA circuit 210 and the input terminals of the OFDM modulation IC 30 in the stage succeeding the IF_VGA circuit 210, and one or more inductance elements (coils L2a and L2b in FIG. 6) are connected to ground.

With this configuration, the parasitic capacitance Cps1 in the input circuit of the OFDM modulation IC 30 and the interposed coils L2a and L2b are tuned to the frequency of an IF signal, and this causes the impedance therebetween to become infinite theoretically. That is, it is possible to cancel out the parasitic capacitance Cps1 in the input circuit of the OFDM modulation IC 30. Thus, it is possible to apparently increase the input impedance of the OFDM modulation IC 30 as seen from the IF_VGA circuit 210.

FIG. 7 is a circuit diagram showing the one-segment tuner module 1 of a sixth embodiment.

As shown in FIG. 7, in the one-segment tuner module 1 of the sixth embodiment, one or more DC blocking capacitor elements (capacitors C4a, C4b, C5a and C5b in FIG. 7) are interposed in series between the differential output terminals of the IF_VGA circuit 210 and the differential input terminals of the OFDM modulation IC 30 in the stage succeeding the IF_VGA circuit 210, and at least one inductance element (a coil L3 in FIG. 7) is interposed between the positive-phase differential signal path and the negative-phase differential signal path.

By interposing the inductance element between the differential signal paths in this way, a parasitic capacitance Cps2 in the differential input circuit of the OFDM modulation IC 30 and the interposed coil L3 are tuned to the frequency of an IF signal, and this causes the impedance between the differential signal paths to become infinite theoretically. That is, it is possible to cancel out the parasitic capacitance Cps2 in the differential input circuit of the OFDM modulation IC 30. Thus, it is possible to apparently increase the input impedance of the OFDM modulation IC 30 as seen from the IF_VGA circuit 210.

FIG. 8 is a circuit diagram showing the one-segment tuner module 1 of a seventh embodiment

As shown in FIG. 8, in the one-segment tuner module 1 of the seventh embodiment, one or more DC blocking capacitor elements (capacitors C6a and C6b in FIG. 8) and one or more resistive elements (resistors R3a and R3b in FIG. 8) are interposed in series between the differential output terminals of the IF_VGA circuit 210 and the differential input terminals of the OFDM modulation IC 30 in the stage succeeding the IF_VGA circuit 210, and one or more inductance elements (coils L4a and L4b in FIG. 8) are interposed between the nodes between the different elements and ground.

With this configuration, as in the fifth embodiment, the parasitic capacitance Cps1 in the input circuit of the OFDM modulation IC 30 and the interposed coils L4a and L4b are tuned to the frequency of an IF signal, and this causes the impedance therebetween to theoretically become infinite. That is, it is possible to cancel out the parasitic capacitance Cps1 in the input circuit of the OFDM modulation IC 30. Thus, it is possible to apparently increase the input impedance of the OFDM modulation IC 30 as seen from the IF_VGA circuit 210.

By interposing the resistors R3a and R3b, as in the first embodiment, it is possible to further increase the apparent input impedance of the OFDM modulation IC 30 as seen from the IF_VGA circuit 210.

FIG. 9 is a circuit diagram showing the one-segment tuner module 1 of an eighth embodiment.

As shown in FIG. 9, in the one-segment tuner module 1 of the eighth embodiment, one or more DC blocking capacitor elements (capacitors C7a and C7b in FIG. 9) and one or more resistive elements (resistors R4a and R4b in FIG. 9) are interposed in series between the differential output terminals of the IF_VGA circuit 210 and the differential input terminals of the OFDM modulation IC 30 in the stage succeeding the IF_VGA circuit 210, and at least one inductance element (a coil L5 in FIG. 9) is interposed between the node between the different elements placed in a positive-phase differential signal path and the node between the different elements placed in a negative-phase differential signal path

By interposing the inductance element between the differential signal paths in this way, as in the sixth embodiment, the parasitic capacitance Cps2 in the differential input circuit of the OFDM modulation IC 30 and the interposed coil L5 are tuned to the frequency of an IF signal, and this causes the impedance between the differential signal paths to become infinite theoretically. That is, it is possible to cancel out the parasitic capacitance Cps2 in the differential input circuit of the OFDM modulation IC 30. Thus, it is possible to apparently increase the input impedance of the OFDM modulation IC 30 as seen from the IF_VGA circuit 210.

Although the embodiments described above deal with a case where the present invention is applied to a one-segment tuner module, the invention is not limited to this application. The invention finds wide application in other kinds of high-frequency modules.

Many modifications and variations are possible without departing from the spirit of the invention in addition to the embodiments described above.

As described above, with a high-frequency module according to the present invention, or a mobile telephone or an electronic device incorporating such a high-frequency module, it is possible to improve the distortion performance of an amplifier circuit and enhance reception sensitivity without increasing consumption current and cost.

With respect to industrial applicability, the technology of the present invention is useful in enhancing the reception sensitivity of a high-frequency module used in a portable television set, a portable DVD device, a mobile telephone, a PMP or the like.

What is claimed is:

1. A high-frequency module comprising:
a mixer circuit performing frequency conversion by mixing a local oscillation signal with a reception signal;
a filter circuit eliminating an unnecessary frequency component from a signal outputted from the mixer circuit;
a controllable-gain amplifier circuit amplifying and outputting a signal outputted from the filter circuit; and
an impedance circuit interposed between an output terminal of the controllable-gain amplifier circuit and an input terminal of a demodulation circuit in a stage succeeding the controllable-gain amplifier circuit so as to apparently increase an input impedance of the demodulation circuit.

2. The high-frequency module of claim 1,
wherein the impedance circuit comprises a resistive element interposed between the output terminal of the controllable-gain amplifier circuit and the input terminal of the demodulation circuit.

3. The high-frequency module of claim 1,
wherein the impedance circuit comprises an inductance element interposed between the output terminal of the controllable-gain amplifier circuit and the input terminal of the demodulation circuit.

4. The high-frequency module of claim 1,
wherein the impedance circuit comprises a chip bead interposed between the output terminal of the controllable-gain amplifier circuit and the input terminal of the demodulation circuit.

5. The high-frequency module of claim 2,
wherein the impedance circuit further comprises a capacitor element that is interposed between the output terminal of the controllable-gain amplifier circuit and the input terminal of the demodulation circuit and is connected in series with the resistive element.

6. The high-frequency module of claim 3,
wherein the impedance circuit further comprises a capacitor element that is interposed between the output terminal of the controllable-gain amplifier circuit and the input terminal of the demodulation circuit and that is connected in series with the inductance element.

7. The high-frequency module of claim 4,
wherein the impedance circuit further comprises a capacitor element that is interposed between the output terminal of the controllable-gain amplifier circuit and the input terminal of the demodulation circuit and that is connected in series with the chip bead.

8. The high-frequency module of claim 1,
wherein the impedance circuit comprises:
a capacitor element interposed between the output terminal of the controllable-gain amplifier circuit and the input terminal of the demodulation circuit; and
an inductance element connected to ground between the output terminal of the controllable-gain amplifier circuit and the input terminal of the demodulation circuit.

9. The high-frequency module of claim 1,
wherein the impedance circuit comprises:
a first capacitor element interposed between a positive-phase differential output terminal of the controllable-gain amplifier circuit and a positive-phase differential input terminal of the demodulation circuit;
a second capacitor element interposed between a negative-phase differential output terminal of the controllable-gain amplifier circuit and a negative-phase differential input terminal of the demodulation circuit; and
an inductance element interposed between a positive-phase differential signal path of and a negative-phase differential signal path of the controllable-gain amplifier circuit.

10. The high-frequency module of claim 8,
wherein the impedance circuit further comprises a resistive element that is interposed between the output terminal of the controllable-gain amplifier circuit and the input terminal of the demodulation circuit and that is connected in series with the capacitor element, and one end of the inductance element is connected to a node between the capacitor element and the resistive element and the other end of the inductance element is grounded.

11. The high-frequency module of claim 9,
wherein the impedance circuit further comprises:
a first resistive element that is interposed between the positive-phase differential output terminal of the controllable-gain amplifier circuit and the positive-phase differential input terminal of the demodulation circuit and that is connected in series with the first capacitor element; and
a second resistive element that is interposed between the negative-phase differential output terminal of the controllable-gain amplifier circuit and the negative-phase differential input terminal of the demodulation circuit and that is connected in series with the second capacitor element, and
one end of the inductance element is connected to a node between the first capacitor element and the first resistive element and the other end of the inductance element is connected to a node between the second capacitor element and the second resistive element.

12. A mobile telephone comprising a high-frequency module,
wherein the high-frequency module comprises:
a mixer circuit performing frequency conversion by mixing a local oscillation signal with a reception signal;
a filter circuit eliminating an unnecessary frequency component from a signal outputted from the mixer circuit;
a controllable-gain amplifier circuit amplifying and outputting a signal outputted from the filter circuit; and
an impedance circuit interposed between an output terminal of the controllable-gain amplifier circuit and an input terminal of a demodulation circuit in a stage succeeding the controllable-gain amplifier circuit so as to apparently increase an input impedance of the demodulation circuit.

13. A mobile electronic device comprising a high-frequency module,
wherein the high-frequency module comprises:
a mixer circuit performing frequency conversion by mixing a local oscillation signal with a reception signal;
a filter circuit eliminating an unnecessary frequency component from a signal outputted from the mixer circuit;
a controllable-gain amplifier circuit amplifying and outputting a signal outputted from the filter circuit; and
an impedance circuit interposed between an output terminal of the amplifier circuit and an input terminal of a demodulation circuit in a stage succeeding the amplifier circuit so as to apparently increase an input impedance of the demodulation circuit.
